(19) United States
(12) Patent Application Publication
(10) Pub. No.: US 2018/0337670 A1
(43) Pub. Date: Nov. 22, 2018

(54) SWITCH LINEARIZATION WITH ANTI-SERIES VARACTOR

(71) Applicant: SKYWORKS SOLUTIONS, INC., Woburn, MA (US)

(72) Inventors: Yu Zhu, Wellesley, MA (US); Dylan Charles Bartle, Arlington, MA (US); Paul T. DiCarlo, Marlborough, MA (US)

(21) Appl. No.: 15/981,086

(22) Filed: May 16, 2018

Related U.S. Application Data
(60) Provisional application No. 62/507,351, filed on May 17, 2017.

(51) Int. Cl. H03K 17/16

(52) U.S. Cl. CPC H03K 17/16; H04B 1/44

(57) ABSTRACT

A radio frequency signal switch is provided and includes an input port and an output port with a signal path including a transistor coupled between the input port and the output port. A first shunt circuit, also including a transistor, has a terminal coupled to the signal path and another terminal coupled to a reference node, and a second shunt circuit including a varactor has a terminal coupled to the signal path and another terminal coupled to the reference node.

### CROSS-REFERENCE TO RELATED APPLICATIONS

This application claims the benefit under 35 U.S.C. § 119(e) of U.S. Provisional Patent Application No. 62/507,351 titled SWITCH LINEARIZATION WITH ANTI-SERIES VARACTOR, filed on May 17, 2017, which is hereby incorporated by reference in its entirety for all purposes.

### BACKGROUND

High data rate applications in communication systems, including wireless communication devices such as cellular telephones, have increasingly stringent requirements for spectral fidelity and efficiency, requiring increased linearity of internal components. Additionally, communication devices are increasingly desired and/or required to operate over a number of different communication bands. These communication devices use one or more instances of transmit and receive circuitry to generate and amplify transmit signals and to amplify and process receive signals, respectively. One or more antennas in such communication devices are typically connected to transmit and receive circuitry through switching circuitry, sometimes referred to as a “transmit/receive switch” or an “antenna switch.” Even in cases where differing antennas are used, two signals of differing frequency may nonetheless have a common signal path and pass through common switching circuitry at some location in the device. Non-linearities in switching circuitry may cause harmonic distortion and intermodulation distortion that make it a challenge to maintain isolation between the two signals. As demand continues to increase for communication devices to handle ever more signal frequencies, non-linearities and intermodulation distortion will continue to be a challenge, and systems and methods to linearize (i.e., to reduce non-linearity) in signal switching components will continue to be of increasing value.

Third-order intermodulation distortion (IMD3) is the measure of the third-order distortion products produced by a nonlinear device when two tones closely spaced in frequency are fed into its input. At least some of these distortion products are usually so close to the original (desired) frequencies that it is almost impossible to filter out the distortion product, and such creates interference challenges in modern multichannel communications equipment.

Conventional approaches to improving IMD3 performance in transistor-based components include increasing bias currents or voltages, increasing size of the transistors (with an associated increase in the component die size), changing the circuit topology, and using advanced process technology in the fabrication of the devices. However, these approaches have associated drawbacks. For example, it is often desirable to minimize the size and power requirements of mobile communication devices, and therefore increasing the die size of components or the bias current/voltage is not necessarily a preferred approach. Similarly, requiring the use of specialized or advanced process techniques can increase the cost of the devices.

### SUMMARY OF THE INVENTION

There is a need to improve IMD3 performance in radio frequency switches and other signal routing components without increasing bias current/voltage while also allowing the use of standard manufacturing processes.

Aspects and embodiments are directed to semiconductor-based electronic components, such as switches, having compensating elements to compensate for non-linearities, so the combined effect is improved linearity to circuits, modules and devices containing such components, and to techniques for achieving the improved linearity through cancellation of harmonics, particularly IMD3 signals, produced in the components during operation.

According to one aspect, a radio frequency signal switch is provided that includes an input port and an output port, a signal path including at least one series transistor coupled between the input port and the output port, a first shunt circuit having a first shunt terminal coupled to the signal path and a second shunt terminal coupled to a reference node, the first shunt circuit including at least one shunt transistor, and a second shunt circuit having a third shunt terminal coupled to the signal path and a fourth shunt terminal coupled to the reference node, the second shunt circuit including at least one varactor.

In some examples, the at least one varactor is a stack of anti-series varactors connected in series between the third shunt terminal and the fourth shunt terminal. Each anti-series varactor may include two field effect transistors, a gate terminal of each of the field effect transistors being electrically connected to the gate terminal of the other field effect transistor to form a common gate terminal, and each of the field effect transistors having a drain terminal electrically connected to a source terminal to form a varactor terminal.

In certain examples, the first shunt circuit may include a plurality of transistors connected in series between the first shunt terminal and the second shunt terminal. Alternately or additionally, the signal path may include a plurality of transistors connected in series between the input port and the output port.

According to some examples, the at least one varactor is configured to produce a first intermodulation product substantially out of phase with a second intermodulation product produced by the at least one shunt transistor.

According to some examples, the at least one varactor is a stack of anti-series varactors connected in series and the first shunt circuit includes a plurality of transistors connected in series, and the stack of anti-series varactors is configured to produce a first intermodulation product substantially out of phase with a second intermodulation product produced by the plurality of transistors connected in series.

According to another aspect, a method of designing a signal switch is provided and includes selecting a series transistor structure to provide a signal path from an input to an output, selecting a shunt transistor structure to provide a shunt path from the signal path to a reference node, and selecting a shunt varactor structure to provide a non-linear capacitance between the signal path and the reference node.

In some examples, selecting the shunt varactor structure includes selecting a number of anti-series varactor pairs to be connected in series at least in part to accommodate an intermodulation distortion product of the shunt transistor structure. The number of anti-series varactor pairs may be selected to accommodate an intermodulation distortion product of the shunt transistor structure at least in part by selecting the anti-series varactor pairs to produce a second intermodulation distortion product out of phase with the intermodulation distortion product of the shunt transistor structure. Selecting the anti-series varactor pairs may include selecting anti-series varactor pairs formed from two field effect transistors having electrically connected gate terminals.

In some examples, selecting the shunt transistor structure includes selecting a number of transistors in series at least in part to accommodate a signal amplitude provided on the signal path. In further examples, selecting the shunt varactor structure includes selecting a number of anti-series varactor pairs to be connected in series at least in part to accommodate an intermodulation distortion product of the shunt transistor structure.

In some examples, selecting the series transistor structure includes selecting a number of transistors in series at least in part to provide an isolation performance figure when the signal switch is in an off state where a signal received at the input is substantially blocked from reaching the output.

According to another aspect, a signal switching device is provided that includes an input port and an output port, a series transistor circuit coupled between the input port and the output port, a transistor stack coupled between the series transistor circuit and a reference node, the transistor stack including a plurality of transistors connected in series, and a varactor stack coupled between the series transistor circuit and the reference node, the varactor stack including a plurality of varactors connected in series.

In certain examples, each of the plurality of varactors is an anti-series varactor. Each anti-series varactor may include two field effect transistors, a gate terminal of each of the field effect transistors being electrically connected to the gate terminal of the other field effect transistor to form a common gate terminal, and each of the field effect transistors having a drain terminal electrically connected to a source terminal.

In some examples, the series transistor circuit includes a plurality of transistors connected in series between the input port and the output port.

In certain examples, the varactor stack is configured to produce a first intermodulation product substantially out of phase with a second intermodulation product produced by the transistor stack.

In certain examples, a number and size of the plurality of varactors is sufficient to produce at least one non-linear signal component of substantially a same amplitude as a non-linear signal component produced by the transistor stack.

Still other aspects, embodiments, examples, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures may be represented by a like numeral. For purposes of clarity, not every component may be labeled in every figure. In the figures:

FIG. 1 is a block diagram of an example of a communication device that may include a signal switch;

FIG. 2 is a graphical representation of third order intermodulation products generated by non-linearities in various signal processing components;

FIG. 3 is a schematic diagram of an example of a signal switch and an equivalent circuit model of the switch in an “on” state;

FIG. 4 is a schematic diagram of one example of a varactor that may be used in a signal switch;

FIG. 5 is a graph of capacitance versus voltage for the varactor of FIG. 4;

FIG. 6 is a pair of graphs illustrating first order and third order capacitance curves for the varactor of FIG. 4;

FIG. 7 is a schematic diagram of another example of a varactor, having an anti-series configuration, that may be used in a signal switch;

FIG. 8 is a pair of graphs illustrating the first order capacitance curve performance of the varactor of FIG. 7;

FIG. 9 is a schematic diagram of an example of a signal switch including a varactor stack in a shunt orientation;

FIG. 10 is a polar plot illustrating third order intermodulation signal strength and phase for various components of the signal switch of FIG. 9;

FIG. 11 is a set of graphs illustrating output signal spectra for various signal switch configurations;

FIG. 12 is a graph of an intermodulation product signal strength relative to a control voltage in the signal switch of FIG. 9;

FIG. 13 is a schematic diagram of another example of a signal switch including a varactor stack in a shunt orientation; and

FIG. 14 is a graph of C-V curves for various polarity combinations in metal oxide semiconductor varactors.

### DETAILED DESCRIPTION

In modern wireless communications devices the antenna switch or transceiver switching circuitry used to achieve multi-mode (e.g., transmit and receive modes) and multi-band operation is an important element. Improving linearity of the switches can be an important design factor. For example, achieving a third order intermodulation distortion (IMD3) performance better than −100 dBm may be desirable. To achieve such performance, the harmonics generated by transistor-based switching arms must be reduced as much as possible.

Accordingly, aspects and embodiments are directed to methods and structures for improving the linearity of semiconductor signal switches through compensation by harmonic cancellation in, e.g., a shunt arm. Semiconductor signal switches often include shunt arms to improve isolation when the switch is in a dis-connected or off state, i.e., wherein a signal arriving at a switch input is substantially rejected and not allowed to pass to a switch output. When the switch is in a connected or on state (allowing the signal to pass from input to output), the shunt arm is “off” (non-conducting) and acts as a non-linear capacitive element. As discussed in more detail below, methods and switches discussed herein include additional components that produce substantially matching harmonics with opposite phase to cancel out the harmonics generated by the shunt arm, thereby achieving a significant reduction in intermodulation products.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, end, side, vertical and horizontal, and the like, are intended for convenience of description, not to limit the present systems and methods or their components to any one positional or spatial orientation.

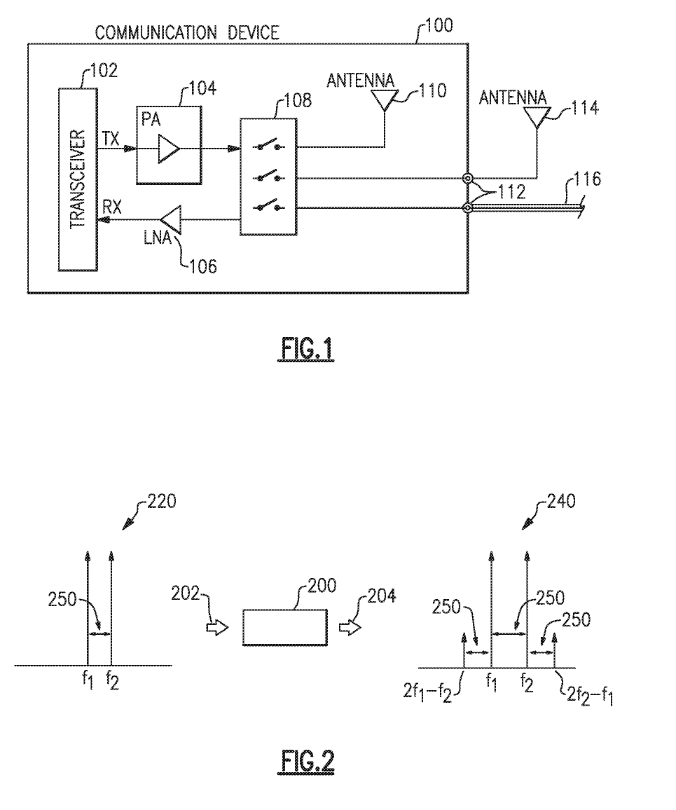

FIG. 1 is a schematic block diagram illustrating a communication device 100 including a transceiver 102 with transmit (TX) and receive (RX) interfaces, a power amplifier (PA) 104 to amplify a transmit signal, a low noise amplifier (LNA) 106 to amplify a receive signal, an antenna switch 108, and an internal antenna 110. A communications device like the communication device 100 may also include one or more connectors 112 to allow connection of, e.g., an external antenna 114 or a communication cable 116. Each of the internal antenna 110, the external antenna 114, and the communication cable 116 may be an interface to another communication device via signals transmitted or received as conveyed by one or more of the antennas and/or cable.

The example of an antenna switch 108 shown in FIG. 1 is a two-by-three (2×3) switch allowing either of the two transceiver signal paths (transmit and receive) to be connected to any of three signal interfaces (the antenna 110, the antenna 114, the cable 116). The particular antenna switch 108 may be implemented through various examples, and other examples of a communication device may have antenna switches of different capabilities. The details of any particular antenna switch are not important, but certain examples of an antenna switch, or other signal routing switches, include one or more transistor-based signal switches in accord with aspects and examples disclosed herein.

Any of the components of the communication device 100 may have non-linear characteristics that contribute to the creation of intermodulation products. Aspects and examples disclosed herein are directed to semiconductor signal switches having improved linearity, and such semiconductor signal switches in accord with aspects and examples disclosed herein may be advantageously used in various signal routing switches, e.g., the antenna switch 108, in various communications devices, such as communication device 100.

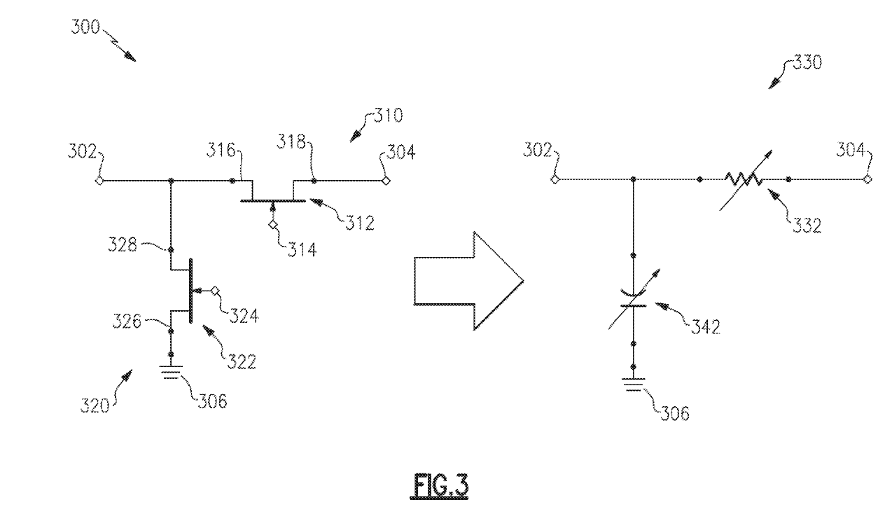

FIG. 2 illustrates the creation of third order intermodulation products by a non-linear component 200. The component 200 receives an input signal 202 and produces an output signal 204. Graph 220 is a graphical representation of an example input signal 202 and illustrates a frequency spectrum of the input signal 202. Graph 240 is a graphical representation of an associated output signal 204 and illustrates the frequency spectrum of the output signal 204. The input signal 202 has two frequency components, f1 and f2, separated from each other by a frequency difference 250. Non-linearites in the component 200 cause the output signal 204 to include not only the original two frequency components f1 and f2, but additional frequency components at frequencies (2f1−f2) and (2f2−f1). These additional frequency components are third order intermodulation products.

Each of the third order intermodulation products has the same frequency difference 250 from its nearest original frequency, f1 or f2, as the frequency difference 250 between f1 and f2. When the original frequencies f1 and f2 are relatively near each other in frequency, the third order intermodulation products are also relatively nearby in frequency, such that it may be difficult to filter out the third order intermodulation products while retaining the original signal frequencies f1 and f2. Accordingly, it is highly valuable to reduce the generation of third order intermodulation products by reducing the non-linearity of the component 200 rather than by attempting to remove the intermodulation products later. The relative power of the intermodulation products is typically expressed in decibels relative to a reference input signal strength, e.g., dBm, and is generally referred to as an IM3 or IMD3 characteristic.

Every component in a system may exhibit non-linear characteristics and may be considered a non-linear component. In some cases the non-linearities may be negligible in the operating frequency range of the component, but in other cases, and generally as frequency bands increase, the effect of non-linearities can become significant, producing intermodulation components that may be a significant challenge to system designers. Accordingly, aspects and examples of transistor-based signal switches, and of methods of design of transistor-based signal switches, in accord with those disclosed herein, provide increased linearity and reduced intermodulation products, especially third order intermodulation products and odd-ordered harmonics.

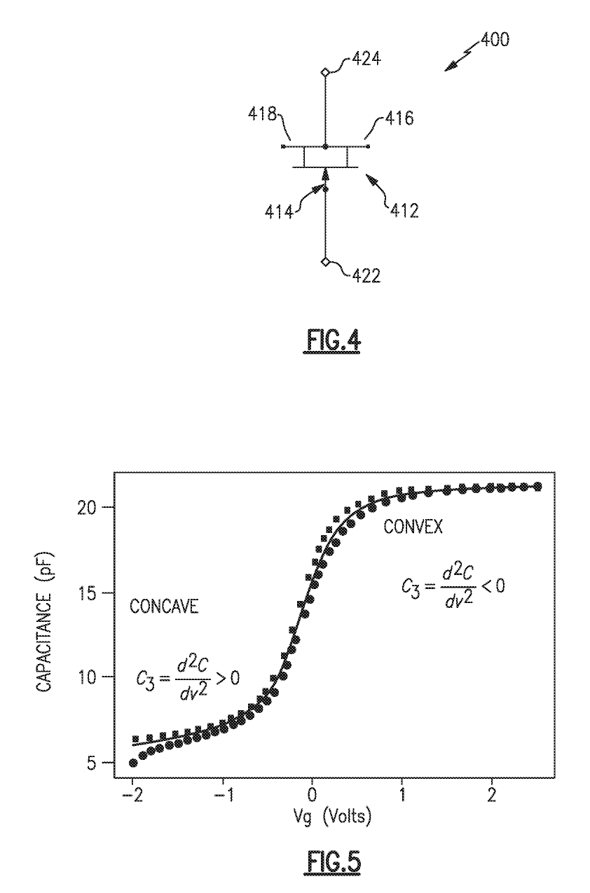

FIG. 3 illustrates one example of a transistor-based signal switch 300 having an input 302 and an output 304, and including a series arm 310 between the input 302 and the output 304 and a shunt arm 320 between the input 302 and ground 306. In various examples, such as in the switch 300, the input 302 and the output 304 may be reversible without affecting the component, e.g., the switch 300. In certain applications, however, the designation of input and output may be of consequence.

The switch 300 includes field effect transistors (FETs) 312, 322 in the series arm 310 and the shunt arm 320, respectively. The transistors 312, 322 may each be one of many types of FETs in the art. For example, each may be a junction FET (JFET) or a metal oxide semiconductor FET (MOSFET), may be a silicon on insulator (SOI) MOSFET, and may be of N-channel or P-channel types, and enhancement or depletion mode types. Each of the transistors 312, 322 has a gate 314, 324, a drain 316, 326, and a source 318, 328. A control voltage applied to, and received at, the gate 314, 324 of each transistor 312, 322 controls the conductivity of a channel between the drain 316, 326 and the source 318, 328. In certain examples, the transistors 312, 322 may be of different types and may be connected in a different way than shown. For example, the source and drain of each may be connected in a manner opposite that shown. Additionally, either or both of the series arm 310 or the shunt arm 320 often include additional transistors connected in series with the transistors 312, 322 shown.

The switch 300 is controllable to be in an on state to conduct a signal received at the input 302 and provide the signal to the output 304 by controlling the series arm to be conducting (on) and controlling the shunt arm to be non-conducting (off) by applying appropriate control voltages to each of the gates 314, 324. In some examples a control voltage may be applied to a gate through a resistor.

The equivalent circuit 330 is an operational model of the switch 300 in a conducting (on) state. In such state, the transistor 312 is controlled to be conducting (on) and is modeled as a non-linear resistor 332, and the transistor 322 is controlled to be non-conducting (off) and is modeled as a non-linear capacitor 342. A signal received at the input 302 experiences the non-linearities of the resistor 332 and the capacitor 342, which produce intermodulation products in an associated output signal provided at the output 304.

For completeness, when the switch 300 is in a non-conducting (off) state, the transistor 312 of the series arm 310 is controlled to be off and the transistor 322 of the shunt arm 320 is controlled to be on. In such state, the switch 300 substantially blocks signals received at the input 302 and does not allow such signals to pass through to the output 304, at least in part due to the transistor 312 presenting a (capacitive) open circuit between the input 302 and the output 304, and the transistor 322 providing a conducting signal path to ground 306, substantially diverting the signal received at the input 302. The focus of this disclosure, however, is when the switch 300 is in the on state to allow a signal to pass, and the transistor 322 (or multiple transistors) in shunt arm 320 acts as a non-linear capacitor. Aspects and examples disclosed herein include features that reduce shunt signal path non-linearities of a transistor-based signal switch while in an on state. For clarity, it should be understood that when the signal switch is in an on state, the shunt signal path is in an off (non-conducting) state, as discussed above.

As discussed above, a transistor like the transistor 322 when in an off state acts as a capacitor with some non-linear characteristics. In particular, a voltage, v, between the drain 326 and the source 328 causes an amount of charge, Q, to be “stored” at the FET channel interfaces and the relationship between Q and v may be modeled as in equation (1).

$$Q = {C}_{1} v + \frac{1}{6} {C}_{3} {v}^{3} \qquad ( 1 )$$

The linear component Q=C₁ v of equation (1) represents the linear component of the capacitance, and if the transistor 322 were entirely linear its overall capacitance would be C=dQ/dv=C₁. In reality, the overall capacitance varies with the voltage, v. The third order component,

$$\frac{1}{6} {C}_{3} {v}^{3} ,$$

is non-linear and is responsible for the third order intermodulation products. Other non-linear components may exist in the relationship between Q and v of an actual transistor, but as discussed above our focus is on the third order intermodulation products because they are likely to be near the desired original frequency components. The value of C₃ for a particular component, e.g., the transistor 322, may be determined as the third derivative of the charge, Q, with respect to the voltage, which is also equal to the second derivative of the overall capacitance, C, with respect to the voltage, as shown in equation (2).

$${C}_{3} = \frac{{d}^{3} Q}{{dv}^{3}} = \frac{{d}^{2} C}{{dv}^{2}} \qquad ( 2 )$$

Referring again to the switch 300 shown in FIG. 3, when two signal tones are conveyed by the switch 300 to a resistive load, R, at the output 304, each signal tone providing a power, P, neglecting any effect of the transistor 312 and assuming the impedance of the signal tones from their source matches the impedance, R, of the load, the IM3 measure (in decibels) of an intermodulation product having angular frequency, ω=2πf, generated by the shunt transistor 322 due to the third order non-linear component of equation (1) is given by equation (3).

$${IM}_{3} = 20 log ( \frac{ω {C}_{3} {R}^{2}}{8} ) + 3 P - 60 \qquad ( 3 )$$

With continued reference to the transistor 322 in FIG. 3, the relationship shown in equation (1) between charge, Q, and voltage, v, (between the drain 326 and the source 328) also depends upon the gate voltage, v_{gs}, applied at the gate 324 relative to the source 328. Accordingly, the value of C₃ depends upon the gate voltage, v_{gs}, and the third order intermodulation products and IM3 value also depend upon the gate voltage, v_{gs}, which, as discussed above, is the control voltage applied to the gate 324 to control the transistor 322 in an on or off state. Further, the value of C₃ may be positive or negative. In certain examples, the gate voltage may be −2.5 volts to turn the transistor 322 off, and the value of C₃ may be positive at this gate voltage.

To reduce the non-linearity of the switch 300 overall, an additional non-linear capacitance is provided to the shunt path of the switch, according to aspects and embodiments disclosed herein. The additional non-linear capacitance at least partially compensates for the non-linearity of the shunt transistor 322 by providing third order intermodulation products that partially cancel, e.g., by phase interference, the intermodulation products generated by the transistor 322. In particular, certain examples of switches include a shunt transistor with a positive C₃ value when in the off state, and a further non-linear element having a negative C₃ value is selected and included to advantageously reduce the overall third order intermodulation products generated. Alternately, certain examples of switches may include a shunt transistor with a negative C₃ value in the off state, and a non-linear element having a positive C₃ value may be selected and included to reduce the overall third order intermodulation products generated.

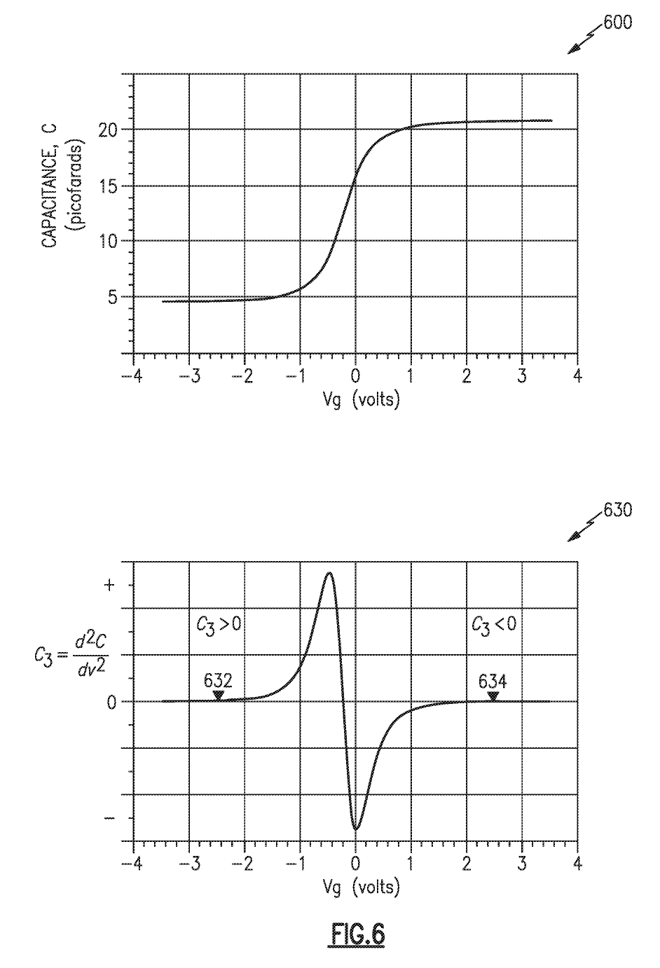

FIG. 4 illustrates an example of a varactor 400 which exhibits a non-linear (variable) capacitance and is fabricated as a field effect transistor 412 having a gate 414 and having an electrically connected drain 416 and source 418 to form a two terminal device, having a first terminal 422 (electrically tied to the gate 414) and a second terminal 424 (electrically tied to the drain 416 and the source 418).

FIG. 5 is a graph of a capacitance curve for the varactor 400, also referred to as a C-V curve as it shows the relationship between capacitance, C, and voltage, v, of the component. As discussed above and with reference to equation (2), the C₃ parameter of a component is the second derivative of the capacitance with respect to the voltage. Accordingly, for increasing voltage on the x-axis of FIG. 5, the concave C-V curve shape for negative gate voltages (v_{gs}) indicates that the C₃ value is positive in that region of the curve. For increasingly positive values of the gate voltage, the C-V curve is convex, indicating that the C₃ value is negative in that region. Accordingly, examples of a varactor similar to the varactor 400 may be advantageously included in a shunt path of a signal switch and controlled to provide non-linear capacitance that at least partially compensates for other non-linear capacitances in the signal switch, such as one or more shunt transistors similar to the shunt transistor 322. Additionally, and in certain examples, many FETs allow substantially no current to flow from the gate to the other terminals of the FET, thus examples of a varactor similar to the varactor 400 may present an open circuit between its terminals and provide essentially only the desired variable non-linear capacitance.

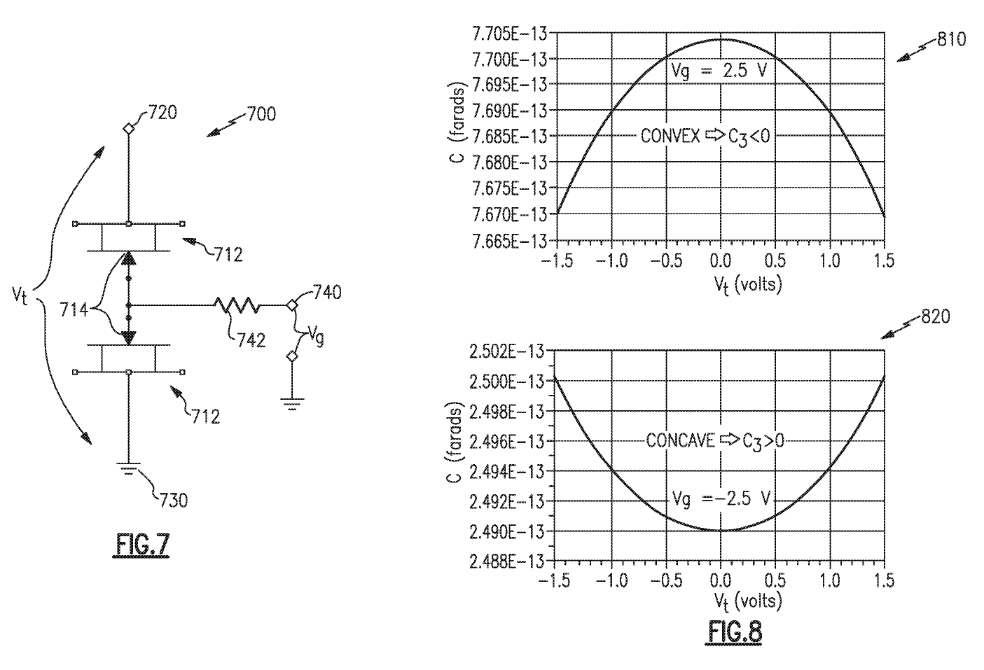

FIG. 6 shows a C-V curve 600 similar to that shown in FIG. 5 for a varactor similar to the varactor 400, and also shows a graph 630 of the third-order C₃ value, which as discussed above is the second derivative of the C-V curve 600 with respect to voltage. The graph 630 shows that the C₃ value is positive at point 632 for a −2.5 v gate voltage and negative at point 634 for a +2.5 v gate voltage. Additionally, the C₃ values at points 632, 634 are relatively flat, indicating that the non-linear effect of the varactor 400 remains essentially the same over some range of gate voltages.

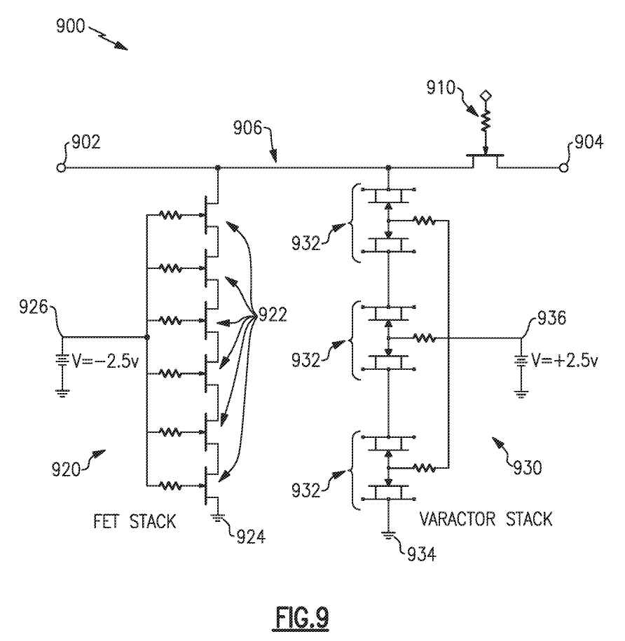

A further aspect of examples of a varactor similar to the varactor 400 is that they may include second, fourth, and further even-order non-linearities. For example, the C-V curve 600 is asymmetric, implying that the varactor 400 exhibits second (and higher) even-order non-linearities. Accordingly, a variation on the varactor 400 is shown in FIG. 7, including a pair of varactors 712 with their gates 714 coupled to form an anti-series varactor 700. The varactor 700 exhibits a non-linear capacitance between its terminals 720, 730 that varies based upon the terminal voltage difference, vₜ, but the varactor 700 formed as an anti-series pair is a symmetrical device while the varactor 400 is not. Accordingly, the two varactors 712 coupled in anti-series cause even-order non-linearities to cancel, which causes the overall varactor 700 to have substantially no even-order non-linearity, unlike the varactor 400 of FIG. 4.

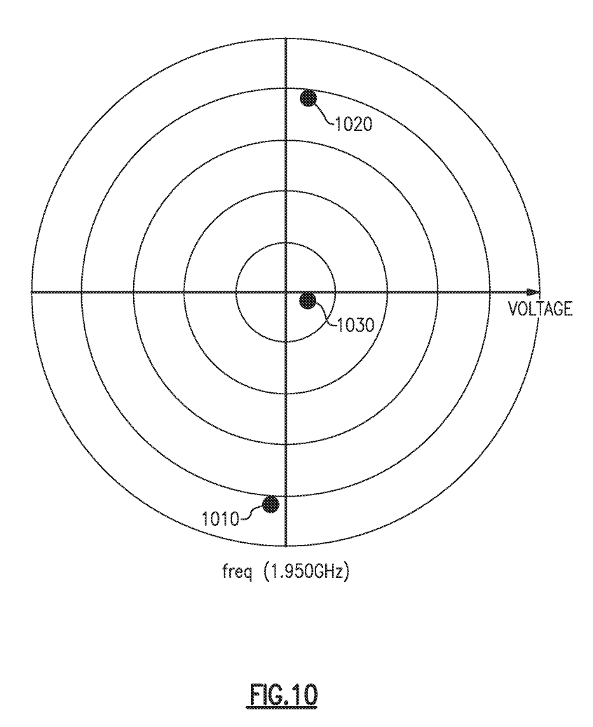

Additionally, the non-linear capacitance may be further affected by a gate voltage, v_{g}, received at the gates 714 from a gate terminal 740, optionally through a gate resistor 742. Accordingly, the gate voltage may be used to adjust the relationship between terminal capacitance and terminal voltage, vₜ, i.e., to adjust the non-linearity of the varactor 700, as illustrated in the curves of FIG. 8.

FIG. 8 shows graphs of a set of C-V curves for one example of an anti-series varactor, such as the anti-series varactor 700. The first graph 810 shows the C-V curve of terminal capacitance, C, versus terminal voltage, vₜ, for an applied gate voltage of +2.5 v and the second graph 820 shows the C-V curve of terminal capacitance, C, versus terminal voltage, vₜ, for an applied gate voltage of −2.5 v. The curve in the first graph 810 is convex, which shows that for the +2.5 v gate voltage the C₃ value is negative. Alternately, the curve in the second graph 820 is concave, showing that a −2.5 v gate voltage causes the varactor 700 to have a positive C₃ value. As discussed above, a shunt transistor such as the shunt transistor 322 in the signal switch 300 of FIG. 3, has a positive C₃ value when controlled to be in the off state. Accordingly, a varactor such as the varactor 700 may be selected, designed, and operated to have a negative C₃ value that offsets a shunt transistor's positive C₃ value, causing the third order intermodulation products of each to substantially cancel each other.

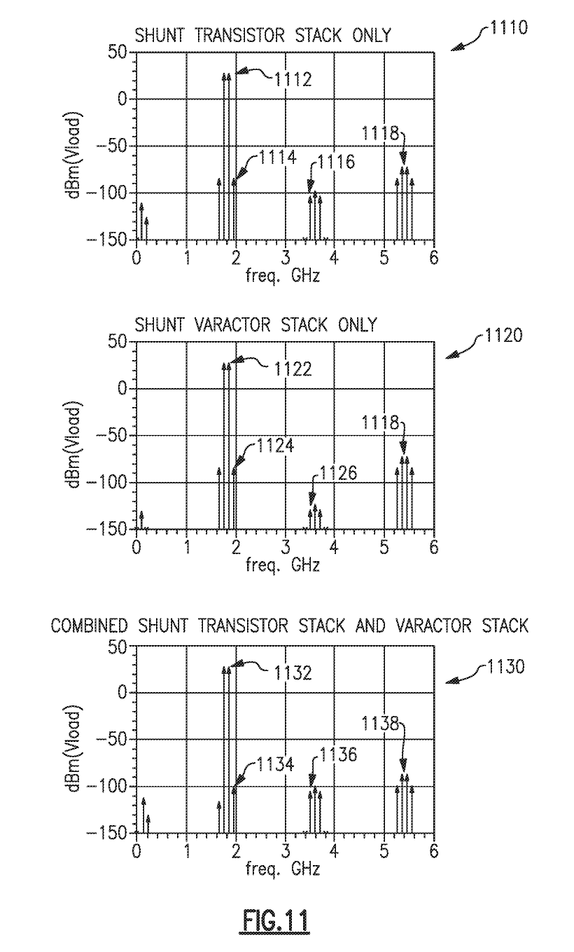

FIG. 9 is a schematic diagram of an example of a linearized transistor-based signal switch 900 including an input 902 and an output 904 at either end of a primary signal path 906, a series transistor 910 along the primary signal path 906, a shunt transistor stack 920, and a shunt varactor stack 930.

The shunt transistor stack 920 includes multiple shunt transistors 922 connected in series between the primary signal path 906 and a reference node 924, which may be a ground reference as shown in FIG. 9, and includes a shunt control voltage input 926 through which a shunt control voltage may be received and is applied to the various gates of the transistors 922.

The shunt varactor stack 930 includes multiple anti-series varactor pairs 932 connected in series between the primary signal path 906 and a reference node 934, which may be a ground reference as shown in FIG. 9, and includes a varactor control voltage input 936 through which a varactor control voltage may be received and is applied to the various gates of the varactor pairs 932. As discussed above, varactor pairs may be used in an anti-series configuration, as shown, to minimize even order non-linearities.

The number, size, and type of transistors 922 may be selected, designed, modeled, or measured to have a known C-V curve and third order non-linearities. Accordingly, the number, size, and type of varactor pairs 932 may be selected, designed, modeled, or measured to have a C-V curve with opposing third order non-linearities, such that intermodulation distortion products produced by the shunt transistor stack 920 are substantially negated by intermodulation distortion products produced by the shunt varactor stack 930.

In certain examples, the varactor pairs 932 may be designed and fabricated of semiconductor types and with fabrication techniques that match those of the transistors 922, thus reducing cost and complexity of the signal switch 900. In various examples, a method of designing a signal switch includes weighing factors of a shunt transistor stack 920 against those of a shunt varactor stack 930 to optimize the total size, cost, and/or production variance of a resulting fabricated signal switch. In some examples, a signal switch may achieve better results with less overall semiconductor die size when a shunt varactor stack is included than a similar signal switch having only a shunt transistor stack. In some examples, the transistors 922 may be of all the same size and type, but in other examples the transistors 922 may vary in size and/or type. In some examples, the varactor pairs 932 may be of all the same size and type, but in other examples the varactor pairs 932 may vary in size and/or type.

As shown in FIG. 9, an example shunt control voltage of −2.5 v at the control input 926 turns off the shunt transistor stack 920 (in keeping with an “on” state of the signal switch 900 overall). As discussed above, each of the transistors 922 has a positive C₃ value when controlled to be in an off state. The example varactor control voltage shown of +2.5 v at the control input 936 of the shunt varactor stack 930, however, places the third order non-linearity of the varactor pairs 932 in a condition to have a negative C₃ value, in opposition to the transistors 922. Accordingly, the third order intermodulation products produced by the shunt varactor stack 930 oppose, or offset, the third order intermodulation products produced by the shunt transistor stack 920. Additionally, in some examples the varactor control voltage (applied to the gates of the anti-series varactor pairs 932) may remain at a fixed voltage, e.g., +2.5 v, regardless of the on or off state of the signal switch 900 overall. For example, when the signal switch 900 is in an off state, the shunt transistor stack 920 may be in an on (conducting) state such that the shunt transistor stack 920 diverts a majority of signal power to the reference node 924, and the impact of the shunt varactor stack 930 in such condition may be insignificant. Accordingly, it may not be necessary to change the varactor control voltage when changing the state of the signal switch 900 from on to off, or vice versa.

In certain examples, the series transistor 910 may be electrically connected in various locations, such as along the primary signal path 906 before or between the connection points of the shunt transistor stack 920 and the shunt varactor stack 930. Additionally, the series transistor 910 may include multiple transistors in series, and in such examples there may be series transistors in any of said locations along the primary signal path 906, i.e., before, between, or after (as shown) the shunt transistor stack 920 and the shunt varactor stack 930. Similarly, in certain examples the physical electrical placement of the shunt transistor stack 920 and the shunt varactor stack 930 may be insignificant, and each may be coupled to the primary signal path 906 at differing locations relative to each other and relative to one or more series transistors 910.

FIG. 10 illustrates an example of the third order intermodulation performance of a shunt transistor stack, a shunt varactor stack designed to match the shunt transistor stack (e.g., for third order intermodulation cancellation), and the combined result of both stacks in a signal switch such as the signal switch 900. In particular, FIG. 10 is a polar plot of signal voltage in the radial dimension and signal phase in the angular dimension for an intermodulation component at 1.95 GHz. Point 1010 represents the third order intermodulation product of a shunt transistor stack including eight SOI MOSFET transistors of six millimeter dimensions, controlled to be in a non-conducting (off) state. The point 1020 represents the third order intermodulation product of a shunt varactor stack including ten SOI MOSFET varactor pairs of one millimeter dimensions, controlled to be in a condition to oppose the non-linearities of the shunt transistor stack. Specifically, the shunt transistor stack (at point 1010) produces intermodulation products with a phase of approximately −90 degrees, while the shunt varactor stack (at point 1020) produces intermodulation products with a phase of approximately +90 degrees. The combination of intermodulation products of both the shunt transistor stack and the shunt varactor stack in a signal switch such as the signal switch 900 substantially cancel each other out to produce the net intermodulation product at point 1030 of significantly lower magnitude than either of the points 1010, 1020.

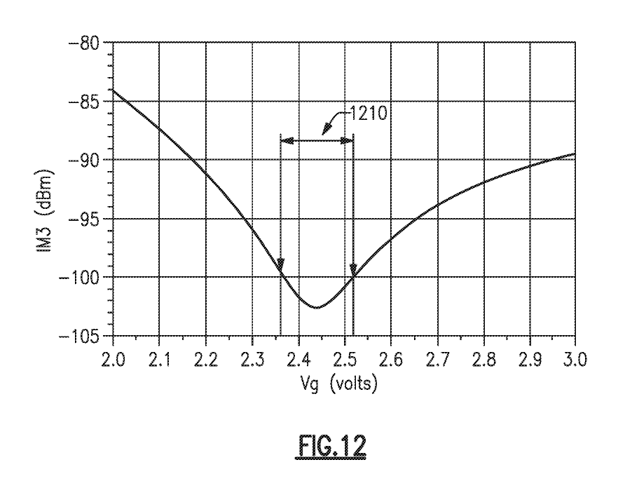

FIG. 11 shows a set of three output signal spectra from three signal switches, each receiving an input signal having a first frequency component at f0=1.75 GHz and a second frequency component at f1=1.85 GHz. Graph 1110 is the output spectrum for a signal switch having only a transistor stack in the shunt path, graph 1120 is the output spectrum for a signal switch having only a varactor stack in the shunt path, and graph 1130 is the output spectrum for a signal switch having a combined transistor stack and varactor stack in the shunt path.

With reference to the graph 1110 for a shunt transistor stack only, the fundamental signal 1112 has a signal strength of approximately 25 dBm. A third order intermodulation product 1114 (e.g., at 1.95 GHz) has a signal strength of about −83 dBm, which is 108 dB below the fundamental signal. A second order harmonic 1116 (i.e., 2f0=3.5 GHz) has a signal strength of about −106 dBm, and a third order harmonic 1118 has a signal strength of about −74 dBm.

By comparison, the graph 1120 for a shunt varactor stack has similar fundamental signal 1122 strength as for the shunt transistor stack only (graph 1110). Additionally, the shunt varactor stack (graph 1120) has similar signal strengths for the third order intermodulation product 1124, and the third harmonic 1128, except that these third order signals are substantially out-of-phase with those in the shunt transistor stack (graph 1110), such that they reduce the overall third order signal strengths when combined with the shunt transistor stack, as in the graph 1130. Still referring to the graph 1120, the second harmonic 1126 generated by the shunt varactor stack has significantly lower signal strength than the shunt transistor stack (graph 1110), because the anti-series varactors included in the varactor stack have reduced second order non-linearities, as discussed above.

The combined result for a signal switch, such as the signal switch 900 in FIG. 9, having both a transistor stack and an anti-series varactor stack in parallel shunt paths, is illustrated by the graph 1130. The fundamental signal 1132 strength remains essentially unchanged at about 25 dBm, indicating that the addition of the shunt varactor stack does not significantly affect the insertion loss characteristic of the switch. The third order intermodulation product 1134 is significantly lower for the combined case, achieving a value of approximately −102.6 dBm, which is almost 20 dB lower as compared to a signal switch having only a transistor stack in the shunt path (e.g., graph 1110). Additionally, the third harmonic 1138 is also significantly improved, at about −89 dBm, which is about 15 dB lower than the transistor stack alone. Finally, the second harmonic 1136 is approximately the same as for the transistor stack alone, because the anti-series varactor stack has minimal second order non-linearity, as discussed above.

The graphs 1110 and 1130 represent a direct comparison of a conventional signal switch (graph 1110) and a signal switch having an anti-series varactor stack in a shunt path (graph 1130), in accord with aspects and examples disclosed herein. As may be seen by comparison of graphs 1110 and 1130, the fundamental signals 1112, 1132, remain essentially unchanged while the third order non-linearities are significantly improved. As discussed above, the third order intermodulation products may be of significant concern because they appear nearby in frequency to the fundamental signals. The graph 1130 for signal switches in accord with aspects and examples disclosed herein show significant improvement in the third order intermodulation product 1134 over that of the unimproved case in the graph 1110 (e.g., 1114).

The performance results discussed above are summarized in Table 1, which is a tabulation of performance of an example signal switch without a shunt varactor stack and an example signal switch (such as the signal switch 900 discussed above) that includes a shunt varactor stack. The table shows values for third order intermodulation, second order harmonic, and third order harmonic for a signal switch receiving an input signal having a first frequency f0=1.75 GHz and a second frequency f1=1.85 GHz. The resulting third order intermodulation products occur at 1.65 GHz and 1.95 GHz, for which the table shows the higher of these.

TABLE 1

| Signal | | | | |
|---|---|---|---|---|
| Switch | f0 | IM3 | 2xf0 | 3xf0 |
| . . . | output level | (1.95 GHz) | output level | output level |
| without | 24.986 dBm | −83.64 dBm | −106.25 dBm | −74.42 dBm |
| Varactor | | | | |
| Stack | | | | |
| with | 24.968 dBm | −102.57 dBm | −105.82 dBm | −89.11 dBm |
| Varactor | | | | |
| Stack | | | | |

FIG. 12 is a graph showing the IM3 characteristic of the combined intermodulation product of, e.g., point 1030 in FIG. 10 or point 1134 in FIG. 11, relative to varactor control (gate) voltage, v_{g}. Of note in the graph of FIG. 12 is a voltage width 1210 of 160 millivolts for a target IM3 of −100 dBm or better. Accordingly, the advantageous effect of the shunt varactor stack may be stable across a range of control voltages.

According to aspects and embodiments disclosed herein, a shunt transistor stack and a shunt varactor stack are designed to work together to reduce intermodulation products in a transistor-based signal switch. Such approaches to signal switches allow a radio frequency (RF) designer to have increased flexibility in the design of the transistor components used in the signal switch. For example, a shunt path having only a transistor stack may be more limited in number, size, and type of transistor elements used in the shunt portion of the signal switch, and any of the number, size, and type of transistor elements may be limited or overly influenced by linearity requirements. Designing a shunt varactor stack in parallel with a shunt transistor stack allows increased flexibility that may allow the total transistor area or die size to be made smaller, or to be made with less linearity and reduced cost in the individual elements, while providing increased linearity in the final component due to the combination of a transistor stack and a varactor stack in a signal switch.

In certain examples, a signal switch in accord with aspects disclosed herein may have, or be designed to have, a certain number and/or size of transistors, in a shunt transistor stack, selected to prevent the transistor channels from reaching a breakdown voltage for a given or expected input signal amplitude. Further, a number and/or size of anti-series varactor pairs, in a shunt varactor stack, may be designed, selected, and/or included to provide non-linear characteristics that produce harmonic and/or intermodulation products substantially equal in magnitude but opposite in phase to any harmonic and/or intermodulation products produced by the shunt transistor stack. Such a shunt transistor stack and a shunt varactor stack may be a matched pair, designed, selected, and/or fabricated to operate in combination to reduce one or more harmonic or intermodulation products when they are, for example, placed in parallel shunt paths as part of a signal switch.

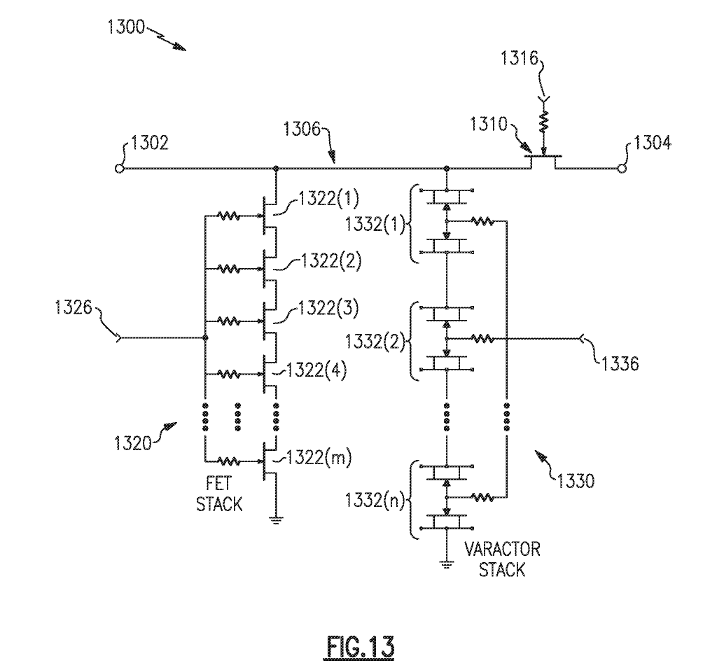

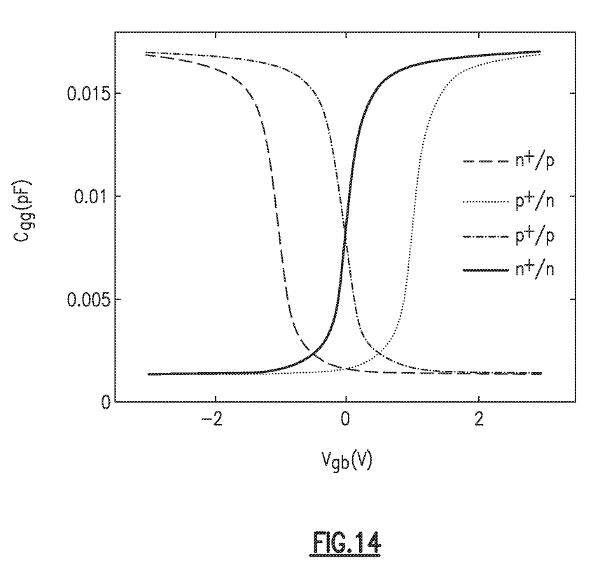

FIG. 13 is a schematic diagram of another example of a linearized transistor-based signal switch 1300, similar to the switch 900 of FIG. 9, including an input 1302 and an output 1304 at either end of a primary signal path 1306, a series transistor 1310 along the primary signal path 1306, a shunt transistor stack 1320, and a shunt varactor stack 1330.

The shunt transistor stack 1320 includes “m” shunt transistors 1322 connected in series and includes a shunt control voltage input 1326 through which a shunt control voltage may be received and applied to the various gates of the transistors 1322. The shunt varactor stack 1330 includes “n” anti-series varactor pairs 1332 connected in series and includes a varactor control voltage input 1336 through which a varactor control voltage may be received and applied to the various gates of the varactor pairs 1332. The primary signal path 1306 may include additional series transistors 1310, which may individually be in any of numerous positions along the primary signal path 1306, as discussed above with reference to the switch 900 of FIG. 9. Additionally, explicitly shown in FIG. 13 is a series control voltage input 1316 through which a series control voltage may be received and applied to the gate(s) of the one or more series transistors 1310.

As discussed above, the number “m” of shunt transistors 1322 in the shunt transistor stack 1320 may be selected based upon numerous considerations, including but not limited to prevention of breakdown voltages developing in the channels of the shunt transistors 1322 under normal signal levels of the switch 1300, and such number “m” may be selected in combination with the materials, configuration, type, size, and the like, of the individual shunt transistors 1322. Also as discussed above, the number “n” of anti-series varactor pairs 1332 in the shunt varactor stack 1330 may also be selected based upon numerous considerations, including but not limited to the third order intermodulation products generated by the shunt transistor stack 1320, such that the shunt varactor stack 1330 tends to negate or cancel out one or more such intermodulation products. Such number “n” of anti-series varactor pairs 1332 may be selected in combination with the materials, configuration, type, size, and the like, of the individual anti-series varactor pairs 1332.

FIG. 14 shows C-V curves for four possible polarity combinations of gate and well layers in MOS varactors. The C-V curves shown in FIG. 14 all have similar shape and are similar to that shown in FIG. 6 for the varactor 400 discussed above. Accordingly, varactors in accord with those disclosed herein may be advantageously constructed of any of a variety of transistor types and technologies. The four curves shown in FIG. 14, for example, illustrate that gates and wells may be p-doped or n-doped in any combination and exhibit similar C-V relationship characteristics to that of the varactor 400 discussed above.

Matched shunt transistor stacks and shunt varactor stacks in accord with aspects and examples disclosed herein, and signal switches in accord with aspects and examples disclosed herein, may be advantageously applied in any number of various devices, modules, or components. For example, signal switches in accord with examples disclosed herein may be included in antenna switches, such as the antenna switch 108 of FIG. 1, or in bypass switches to route around various other components such as amplifiers, attenuators, and the like, or in electromagnetic couplers used for sensing signals for analysis or power measurements, reflections, mismatches, etc., and in such couplers or other components a switch may route signals to various elements, inputs, outputs, termination impedance elements, filters, and the like.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A radio frequency signal switch, comprising:
an input port and an output port;
a signal path including at least one series transistor coupled between the input port and the output port;
a first shunt circuit having a first shunt terminal coupled to the signal path and a second shunt terminal coupled to a reference node, the first shunt circuit including at least one shunt transistor; and
a second shunt circuit having a third shunt terminal coupled to the signal path and a fourth shunt terminal coupled to the reference node, the second shunt circuit including at least one varactor.

2. The radio frequency signal switch of claim 1 wherein the at least one varactor is a stack of anti-series varactors connected in series between the third shunt terminal and the fourth shunt terminal.

3. The radio frequency signal switch of claim 2 wherein the first shunt circuit includes a plurality of transistors connected in series between the first shunt terminal and the second shunt terminal.

4. The radio frequency signal switch of claim 2 wherein the signal path includes a plurality of transistors connected in series between the input port and the output port.

5. The radio frequency signal switch of claim 2 wherein each anti-series varactor includes two field effect transistors, a gate terminal of each of the field effect transistors being electrically connected to the gate terminal of the other field effect transistor to form a common gate terminal, and each of the field effect transistors having a drain terminal electrically connected to a source terminal to form a varactor terminal.

6. The radio frequency signal switch of claim 1 wherein the at least one varactor is configured to produce a first intermodulation product substantially out of phase with a second intermodulation product produced by the at least one shunt transistor.

7. The radio frequency signal switch of claim 1 wherein the at least one varactor is a stack of anti-series varactors connected in series and the first shunt circuit includes a plurality of transistors connected in series, and the stack of anti-series varactors is configured to produce a first intermodulation product substantially out of phase with a second intermodulation product produced by the plurality of transistors connected in series.

8. A method of designing a signal switch, comprising:
selecting a series transistor structure to provide a signal path from an input to an output;
selecting a shunt transistor structure to provide a shunt path from the signal path to a reference node; and
selecting a shunt varactor structure to provide a non-linear capacitance between the signal path and the reference node.

9. The method of claim 8 wherein selecting the shunt varactor structure includes selecting a number of anti-series varactor pairs to be connected in series at least in part to accommodate an intermodulation distortion product of the shunt transistor structure.

10. The method of claim 9 wherein selecting the number of anti-series varactor pairs to accommodate an intermodulation distortion product of the shunt transistor structure includes selecting the anti-series varactor pairs to produce a second intermodulation distortion product out of phase with the intermodulation distortion product of the shunt transistor structure.

11. The method of claim 9 wherein selecting the anti-series varactor pairs includes selecting anti-series varactor pairs formed from two field effect transistors having electrically connected gate terminals.

12. The method of claim 8 wherein selecting the shunt transistor structure includes selecting a number of transistors in series at least in part to accommodate a signal amplitude provided on the signal path.

13. The method of claim 12 wherein selecting the shunt varactor structure includes selecting a number of anti-series varactor pairs to be connected in series at least in part to accommodate an intermodulation distortion product of the shunt transistor structure.

14. The method of claim 8 wherein selecting the series transistor structure includes selecting a number of transistors in series at least in part to provide an isolation performance figure when the signal switch is in an off state where a signal received at the input is substantially blocked from reaching the output.

15. A signal switching device, comprising:
an input port and an output port;
a series transistor circuit coupled between the input port and the output port;
a transistor stack coupled between the series transistor circuit and a reference node, the transistor stack including a plurality of transistors connected in series; and
a varactor stack coupled between the series transistor circuit and the reference node, the varactor stack including a plurality of varactors connected in series.

16. The signal switching device of claim 15 wherein each of the plurality of varactors is an anti-series varactor.

17. The signal switching device of claim 16 wherein each anti-series varactor includes two field effect transistors, a gate terminal of each of the field effect transistors being electrically connected to the gate terminal of the other field effect transistor to form a common gate terminal, and each of the field effect transistors having a drain terminal electrically connected to a source terminal.

18. The signal switching device of claim 15 wherein the series transistor circuit includes a plurality of transistors connected in series between the input port and the output port.

19. The signal switching device of claim 15 wherein the varactor stack is configured to produce a first intermodulation product substantially out of phase with a second intermodulation product produced by the transistor stack.

20. The signal switching device of claim 15 wherein a number and size of the plurality of varactors is sufficient to produce at least one non-linear signal component of substantially a same amplitude as a non-linear signal component produced by the transistor stack.
